(19) United States
(12) Patent Application Publication
(10) Pub. No.: US 2026/0146876 A1
(43) Pub. Date: May 28, 2026

(54) CHANNEL STRUCTURE, FLUID MEASUREMENT APPARATUS, AND FLUID CONTROL APPARATUS

(71) Applicants: IHARA SCIENCE CORPORATION, Tokyo (JP); HORIBA STEC, Co., Ltd., Kyoto-shi (JP)

(72) Inventors: Miyoshi KIMURA, Isesaki-shi (JP); Toru KISHI, Higashine-shi (JP); Tadahiro YASUDA, Kyoto-shi (JP)

(21) Appl. No.: 19/400,981

(22) Filed: Nov. 25, 2025

(30) Foreign Application Priority Data
Nov. 28, 2024 (JP) 2024-207399
Aug. 28, 2025 (JP) 2025-142679

(51) Int. Cl. G01F 1/42

(52) U.S. Cl. CPC G01F 1/42

(57) ABSTRACT

The present invention fixes a fluidic resistor member while ensuring sealability, without applying unnecessary force thereto. The fluidic resistor member includes: pipe members each forming a channel; a fluidic resistor member that is made of ceramic, that is provided in the channel, and that has one or more resistor channels; and a fixing mechanism that fixes the fluidic resistor member to the channel by being nipped between the pipe members. The fixing mechanism includes a seal that provides sealing on an outer peripheral surface of the fluidic resistor member and a press-fixing portion that fixes the fluidic resistor member by pressing the outer peripheral surface of the fluidic resistor member. The seal and the press-fixing portion are provided at least at different positions in an axial direction of the fluidic resistor member.

### CROSS-REFERENCE TO RELATED APPLICATION(S)

The present application claims priority to Japanese Patent Application No. 2024-207399 filed Nov. 28, 2024, and Japanese Patent Application No. 2025-142679 filed Aug. 28, 2025, both of which are incorporated herein by reference in their entireties.

### BACKGROUND OF THE INVENTION

### Technical Field

The present invention relates to a channel structure, a fluid measurement apparatus, and a fluid control apparatus.

### Description of the Related Art

As a conventional fluidic resistor element, there is a fluidic resistor element formed as a ceramic cylinder including a plurality of resistor channels each having a very small diameter, as disclosed in JP 2024-27783 A. Compared with a conventional fluidic resistor element made of a metal, such a ceramic fluidic resistor element exhibits physical properties such as a near-zero thermal expansion coefficient, a high degree of hardness, and excellent heat resistance and corrosion resistance, and, therefore, enables very accurate flow rate measurements, particularly when the flow rate to be controlled is low.

In JP 2024-27783 A, in order to fix the ceramic fluidic resistor member to the channel, a metallic covering member is provided in a manner covering the outer peripheral surface of the fluidic resistor member, and is tightened by crimping the fluidic resistor member by applying a force radially from the outside, thereby ensuring sealability while fixing the fluidic resistor member at the same time.

### PRIOR ART DOCUMENT

### Patent Document

JP 2024-27783 A

### SUMMARY OF THE INVENTION

However, with the structure disclosed in JP 2024-27783 A, because the fluidic resistor member is fixed and the sealability is ensured at the same point by crimping the covering member, there is a risk of the ceramic cracking, due to the stress applied to ensure the sealability. This risk makes it difficult to fix the fluidic resistor member while ensuring the sealability.

In view of the foregoing, the present invention is made to address the challenge described above, and it is a main object of the present invention to fix a fluidic resistor member while ensuring sealability without applying an unnecessary force to the fluidic resistor member.

In other words, a channel structure according to the present invention includes: pipe members each forming a channel through which a fluid flows; a fluidic resistor member that is made of ceramic, that is provided to the channel, and that has one or more resistor channels; and a fixing mechanism that fixes the fluidic resistor member to the channel by being nipped between the pipe members, in which the fixing mechanism includes: a seal that provides sealing on an outer peripheral surface of the fluidic resistor member; and a press-fixing portion that fixes the fluidic resistor member by pressing the outer peripheral surface of the fluidic resistor member, in which the seal and the press-fixing portion are provided at positions different from each other in an axial direction of the fluidic resistor member.

With this channel structure, because the seal and the press-fixing portion are provided at positions different from each other in the axial direction of the fluidic resistor member, it is not necessary to ensure the sealability with the press-fixing portion, so that the stress applied to the fluidic resistor member can be reduced. Furthermore, by providing the seal separately from the press-fixing portion, it is possible to configure the seal using a member having excellent sealability such as a resin member to ensure the sealability, without the need for deforming the seal using a crimp or the like that is a metal member. As a result, it is possible to fix the fluidic resistor member while ensuring the sealability, without applying an unnecessary force to the fluidic resistor member.

Preferably, the fixing mechanism further includes: a gasket that has an annular shape, that is provided on the outer peripheral surface of the fluidic resistor member, and that is nipped between the pipe members; and a fixing member that has a tubular shape, and is provided on the outer peripheral surface of the fluidic resistor member, on one side or the other side of the gasket, in which the seal is provided between the outer peripheral surface of the fluidic resistor member and an inner peripheral surface of the fixing member, to provide sealing between the outer peripheral surface and the inner peripheral surface, and the press-fixing portion is provided by the fixing member.

With this configuration, the fluidic resistor member can be provided to the channel by nipping the annular gasket between the pair of pipe members, and the force for nipping the pair of pipe members is not exerted on the fluidic resistor member, so that it is possible to prevent breakage or the like of the fluidic resistor member.

Preferably, the fixing member is provided on each of one side and the other side of the gasket, and fixes the gasket by nipping.

With this configuration, it is possible to achieve a structure in which the two fixing members and the fluidic resistor member are fixed to the gasket, and the fluidic resistor member can be prevented from being displaced, regardless of the direction in which the fluid flows in the fluidic resistor member.

Preferably, the seal further provides sealing between the gasket and a facing surface of each of the fixing members.

With this configuration, it is possible to prevent a leakage of the fluid from the gap between the gasket and the fluidic resistor member, through the gap between the gasket and the fixing members.

Preferably, a facing surface of the fixing member has an inclined pressing surface that presses the seal toward the outer peripheral surface of the fluidic resistor member and a facing surface of the gasket.

With this configuration, by pressing the seal with the pressing surface, sealing between the outer peripheral surface of the fluidic resistor member and the inner peripheral surface of the fixing member, and sealing between the facing surfaces of the gasket and the fixing members can both be achieved at the same time.

A channel structure according to the present invention includes: pipe members each forming a channel through which a fluid flows; a fluidic resistor member that is made of ceramic, that is provided to the channel, and that has one or more resistor channels; a fixing mechanism that fixes the fluidic resistor member to the channel by being nipped between the pipe members, in which the fixing mechanism includes: a seal made of an elastic material that provides sealing on an outer peripheral surface of the fluidic resistor member; a gasket that has an annular shape, that is provided on the outer peripheral surface of the fluidic resistor member, and that is nipped between the pipe members; a fixing member that has a tubular shape, and that is provided on an outer peripheral surface of the fluidic resistor member on one side or the other side of the gasket; an intermediate support portion that has a tubular shape, and that is provided between the outer peripheral surface of the fluidic resistor member and an inner peripheral surface of the fixing member; and a press-fixing portion that fixes the fluidic resistor member by pressing the outer peripheral surface of the fluidic resistor member, in which the seal and the press-fixing portion are provided at positions different from each other in an axial direction of the fluidic resistor member, and the intermediate support portion extends outward from an end face of the fixing member, on an opposite side of an end face that is in contact with the gasket.

With this configuration, the areas of the seals can be increased by the intermediate support portion, so that the sealing performance can be improved. Furthermore, because the intermediate support portions extend outward, the seal members are reliably brought into contact with the end faces of the respective fixing members, and stable sealing is maintained, so that it is possible to ensure high reliability of the seals over a long time period.

As a specific embodiment of the press-fixing portion, preferably, the press-fixing portion is provided on an opposite side of an end face of the fixing member, the end face being an end face that is in contact with the gasket.

Preferably, the end face of the fixing member is provided with an annular groove, the end face being the end face on the opposite side of the end face that is in contact with the gasket, and the press-fixing portion is formed by compressing an inner portion that is nearer to the fluidic resistor member than the groove.

With this configuration, because the groove is formed on the end face of the fixing member, and the press-fixing portion is formed by compressing the portion on the inner side of the groove, it is possible to simplify the configuration of the press-fixing portion. Furthermore, by providing the groove on the radially inner side in the end face, the portion (annular portion) to be compressed can be kept thin, so that it is possible to make the compression easy, and the fluidic resistor member can be fixed while reducing the stress applied to the fluidic resistor member.

Preferably, the press-fixing portion is formed by compressing an outer peripheral surface of the fixing member, on an opposite side of the end face that is in contact with the gasket.

With this configuration, it is possible to achieve the press-fixing portion by compressing the outer peripheral surface of the fixing member, so that the freedom in the processing can be improved, without limiting the compression to the end face. In particular, when the seal has the tubular portion described above, the pressing force resultant of compression is exerted on the fluidic resistor member in a manner distributed by the tubular portion, so that concentration of stress can be suppressed, and a stable seal can be achieved while preventing damage and deformation of the fluidic resistor member.

Furthermore, a fluid measurement apparatus according to the present invention includes the channel structure described above, an upstream pressure sensor that measures a pressure upstream of the fluidic resistor member in the channel, and a downstream pressure sensor that measures a pressure downstream of the fluidic resistor member in the channel.

In this fluid measurement apparatus, because a ceramic fluidic resistor member is used as the fluidic resistor element, highly accurate fluid measurements can be achieved.

Furthermore, a fluid control apparatus according to the present invention includes the channel structure described above; an upstream pressure sensor that measures a pressure upstream of the fluidic resistor member in the channel; a downstream pressure sensor that measures a pressure downstream of the fluidic resistor member in the channel; and a fluid control valve provided upstream or downstream of the fluidic resistor member in the channel.

According to the present invention, it is possible to fix the fluidic resistor member and to ensure the sealability, without applying an unnecessary force to the fluidic resistor member.

### BRIEF DESCRIPTION OF THE DRAWINGS

FIG. 1 is a schematic diagram illustrating a configuration of a fluid measurement apparatus according to one embodiment of the present invention;

FIG. 2 is a partially enlarged cross-sectional view of a channel structure according to the embodiment;

FIG. 3 is a schematic view illustrating a clamp joint that is a coupling mechanism according to the embodiment;

FIG. 4 is an enlarged cross-sectional view illustrating a fluidic resistor member and a fixing mechanism according to the embodiment;

FIG. 5 is a schematic view illustrating a mechanism for fixing the fluidic resistor member by a press-fixing portion according to the embodiment;

FIG. 6 is a cross-sectional view illustrating a method of assembling the fixing mechanism according to the embodiment;

FIG. 7 is an enlarged cross-sectional view illustrating a fluidic resistor member and a fixing mechanism according to a modification;

FIG. 8 is a schematic view illustrating a mechanism for fixing a fluidic resistor member using a press-fixing portion according to a modification;

FIG. 9 is a cross-sectional view illustrating a method of assembling the fixing mechanism according to the embodiment; and

FIG. 10 is an enlarged cross-sectional view illustrating structures around the fluidic resistor member according to a modification.

### DETAILED DESCRIPTION

### Embodiment of Present Invention

A fluid measurement apparatus according to one embodiment of the present invention will now be explained with reference to some drawings. Note that all of the drawings described below may be schematic representations, with some omissions and exaggerations made as appropriate, to facilitate understanding. The same elements are denoted by the same reference signs, and the descriptions thereof will be omitted as appropriate.

### Configuration of Apparatus

This fluid measurement apparatus 100 according to the embodiment is used in various processes such as a semiconductor manufacturing process, and is provided to one or more gas supply lines that are connected to a semiconductor processing chamber, as an example, so as to measure the flow rate of a process gas flowing through each of the gas supply lines.

Specifically, the fluid measurement apparatus 100 includes: a channel structure 10 that forms a channel R through which a fluid such as a gas flows, and is provided with a fluidic resistor member 2; an upstream pressure sensor 20 that measures a pressure upstream of the fluidic resistor member 2 in the channel R; a downstream pressure sensor 30 that measures the pressure downstream of the fluidic resistor member 2 in the channel R; and a flow rate calculation unit 50 that measures the flow rate of the fluid on the basis of the measured upstream pressure and downstream pressure.

The channel structure 10 includes a pair of pipe members 11a, 11b forming the channel R, a ceramic fluidic resistor member 2 provided in the channel R, and a coupling mechanism 12 coupling the pair of pipe members 11a, 11b.

An inlet port P1 through which a fluid enters is provided to the upstream end of one pipe member 11a, and an outlet port P2 through which the fluid exits is provided to the downstream end of the other pipe member 11b. The downstream end of the one pipe member 11a is provided with a flange 111 to be connected to the other pipe member 11b via the coupling mechanism 12, and the upstream end of the other pipe member 11b is provided with another flange 111 to be connected to the one pipe member 11a via the coupling mechanism 12.

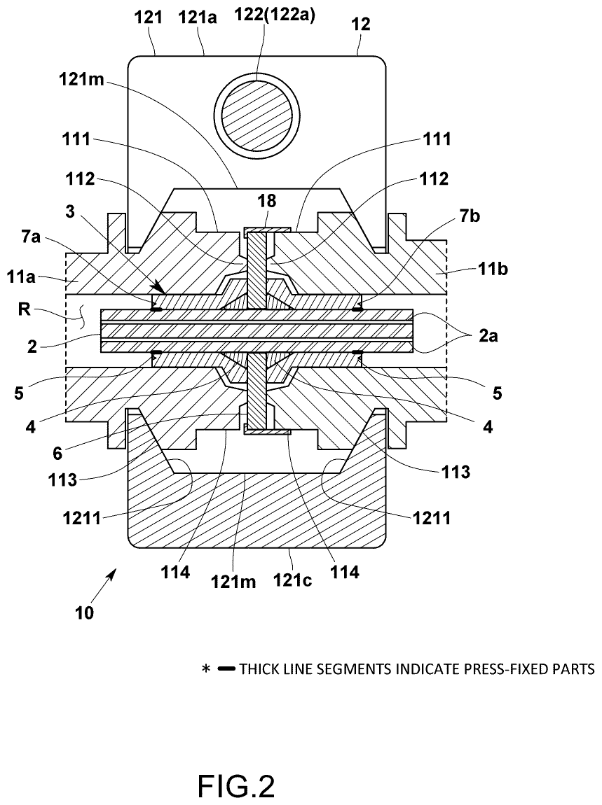

As illustrated in FIG. 2, the tip end face of each of these flanges 111 has an annular protrusion 112 that wedges into a gasket, to be described later. On the rear face of each of the flanges 111 in the axial direction, the rear face being on the opposite side of the tip end face, an inclined surface 113 having a diameter increasing toward the tip end is provided. On the outer peripheral surface of each of the flanges 111, a stepped portion 114 having a diameter becoming smaller is provided. On the stepped portion 114, an alignment holder, to be described later, is mounted.

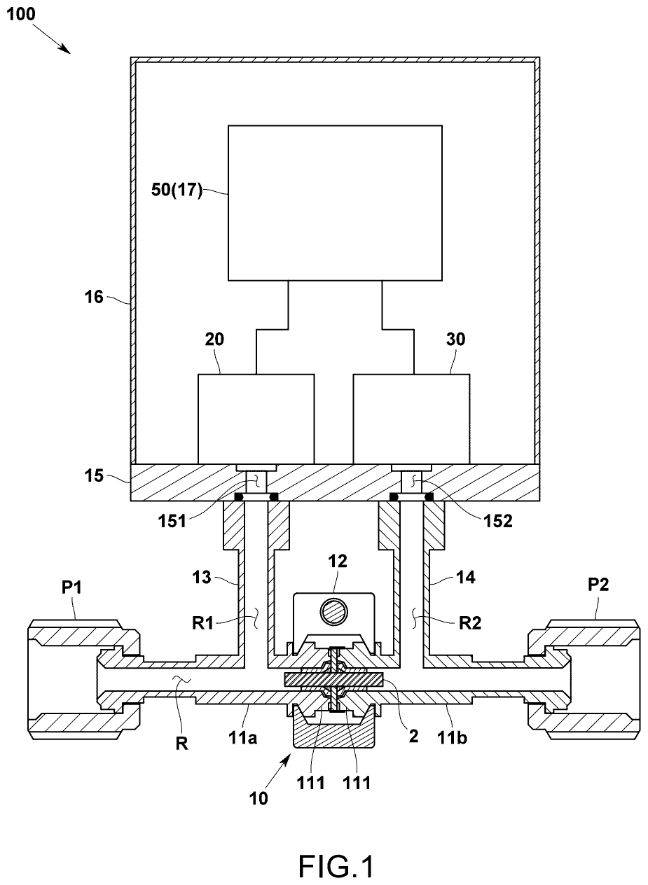

Furthermore, as illustrated in FIG. 1, to the one pipe member 11a, an upstream branch pipe 13 having an upstream measurement channel R1 for measuring the pressure upstream of the fluidic resistor member 2 is connected. To the other pipe member 11b, a downstream branch pipe 14 having a downstream measurement channel R2 for measuring the pressure downstream of the fluidic resistor member 2 is connected.

An upstream pressure sensor 20 and a downstream pressure sensor 30 are connected to the upstream branch pipe 13 and the downstream branch pipe 14, respectively, with a connection plate 15 therebetween. The connection plate 15 has an upstream communication passage 151 allowing the upstream measurement channel R1 to communicate with the upstream pressure sensor 20, and a downstream communication passage 152 allowing the downstream measurement channel R2 to communicate with the downstream pressure sensor 30. To the connection plate 15, the upstream pressure sensor 20 and the downstream pressure sensor 30 are fixed, and a housing 16 that houses the upstream pressure sensor 20 and the downstream pressure sensor 30 is fixed. A circuit board 17 functioning as a flow rate calculation unit 50 that measures the flow rate of the fluid on the basis of the upstream pressure and the downstream pressure is fixed to the connection plate 15 or to the housing 16.

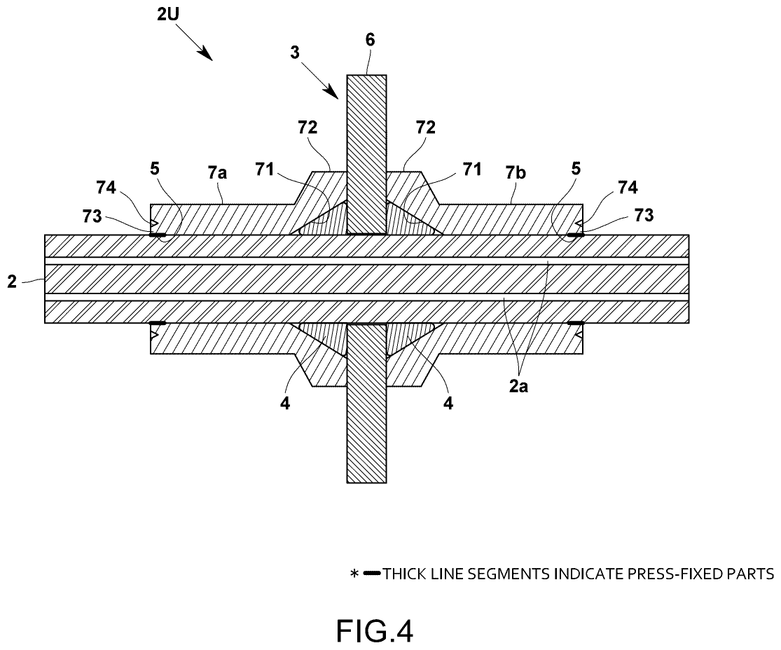

The fluidic resistor member 2 serves as resistance when the fluid flows, and has one or more resistor channels 2a, as illustrated in FIGS. 2 and 4. The fluidic resistor member 2 is made of a ceramic such as quartz, alumina, zirconia, or silicon nitride. Specifically, the fluidic resistor member 2 has a cylindrical shape, and has one or more resistor channels 2a extending along the axial direction. The fluidic resistor member 2 has a diameter (outer diameter) of about several millimeters (e.g., 1.5 mm) and a length (dimension in the axial direction) of about several millimeters to several tens millimeters (e.g., 7 mm), for example, but these sizes may be changed as appropriate.

In this embodiment, the aspect ratio, which is the ratio of the length with respect to the diameter of the resistor channel 2a, is 200 or higher, and preferably 300 or higher. The aspect ratio and the number of the resistor channels 2a determine the resistance of the fluidic resistor member 2.

As illustrated in FIGS. 1 and 2, the coupling mechanism 12 couples the pair of pipe members 11a, 11b, with the flanges 111 of the pair of pipe members 11a, 11b facing each other. Specifically, the coupling mechanism 12 includes a clamp joint.

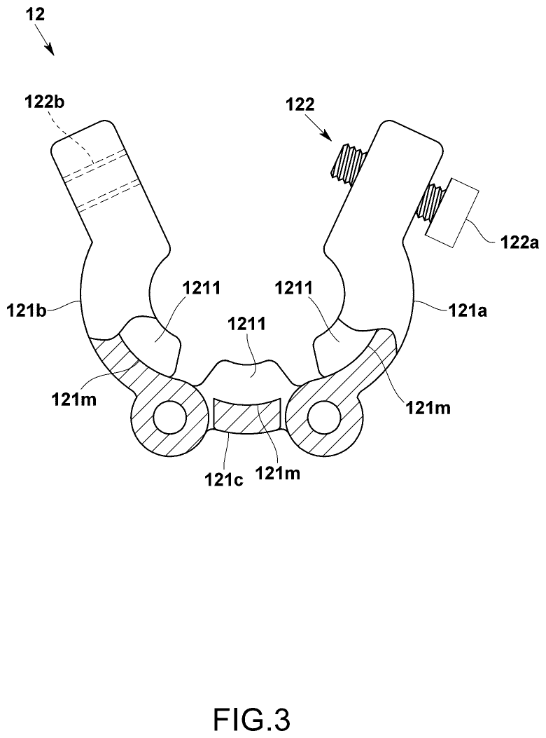

The clamp joint 12 is fitted to the facing flanges 111 from the outside, to fasten and to couple the flanges 111. Specifically, as illustrated in FIGS. 2 and 3, the clamp joint 12 includes a clamp body 121 the inner peripheral surface of which is provided with a recessed groove 121m extending in the circumferential direction, and a fastener 122 that fastens the clamp body 121 in a manner reducing the inner diameter of the clamp body 121.

The clamp body 121 has a series of clamp elements (in the example herein, three clamp elements) 121a to 121c adjacent ones of which are connected rotatably with respect to each other. Each of the clamp elements 121a to 121c is made of stainless steel such as SUS316, for example. On the inner peripheral surface of each of the clamp elements 121a to 121c, a recessed groove 121m having such a width that the outer peripheral edge of the pair of facing flanges 111 can be fitted is provided in a manner extending in the circumferential direction. On the inner surfaces of the pair of side wall portions forming the recessed groove 121m, inclined surfaces 1211 corresponding to the inclined surfaces 113 of the respective flanges 111 are provided.

The fastener 122 fastens the free ends of the outer clamp elements 121a, 121b, forming a pair, to each other. Specifically, as illustrated in FIG. 3, the fastener 122 includes a bolt member 122a that is provided in a manner rotatable inside a through-hole provided to the free end of one outer clamp element 121a, and a female screw hole 122b provided to the free end of the other outer clamp element 121b. The bolt member 122a is made of stainless steel such as SUS316. By screwing the bolt member 122a into the female screw hole 122b, the pair of outer clamp elements 121a, 121b is connected to each other, and the inner peripheral diameter of the clamp body 121 can be increased or reduced. As the inner peripheral diameter of the clamp body 121 is reduced, the inclined surfaces 1211 of the clamp elements 121a to 121c press the inclined surfaces 113 of the flanges 111, and the flanges 111 are pressure-bonded to each other by the axial component of the pressing force.

### Fixing Mechanism 3 for Fluidic Resistor Member 2 in Channel Structure 10

As illustrated in FIGS. 2 and 4, the channel structure 10 according to the embodiment includes a fixing mechanism 3 that fixes the fluidic resistor member 2 to the channel, by being nipped between the pair of pipe members 11a, 11b.

The fixing mechanism 3 includes seals 4 made of an elastic material for providing sealing to the outer peripheral surface of the fluidic resistor member 2, and press-fixing portions 5 that press and fix the outer peripheral surface of the fluidic resistor member 2. The seals 4 are provided at positions different from the press-fixing portions 5 in the axial direction of the fluidic resistor member 2.

Specifically, the fixing mechanism 3 further includes an annular gasket 6 provided on the outer peripheral surface of the fluidic resistor member 2, and nipped between the pair of pipe members 11a, 11b, and a pair of fixing members 7a, 7b provided on the outer peripheral surface of the fluidic resistor member 2 on the respective sides of the gasket 6.

The gasket 6 is nipped between the flanges 111 of the pair of pipe members 11a, 11b, and provides sealing between the pair of pipe members 11a, 11b. Specifically, as a result of the pair of pipe members 11a, 11b being connected with the clamp joint that is the coupling mechanism 12, the protrusions 112 of the respective flanges 111 wedge into the gasket 6, and provide sealing between the pair of pipe members 11a, 11b. The gasket 6 according to the embodiment has an annular shape, and the fluidic resistor member 2 is disposed inside a through-hole provided at the center of the gasket 6. The gasket 6 is made of stainless steel such as SUS316.

The pair of fixing members 7a, 7b is provided on the respective sides of the gasket 6, and fixes the gasket 6 by nipping the gasket 6 therebetween. The fixing members 7a, 7b according to the embodiment have through-holes, respectively, each having a circular cross section into which the fluidic resistor member 2 is inserted. The fixing members 7a, 7b are also fixed to the fluidic resistor member 2 by the press-fixing portions 5, to be described later. By fixing the pair of fixing members 7a, 7b to the fluidic resistor member 2, the gasket 6, the fluidic resistor member 2, and the pair of fixing members 7a, 7b are integrated as a unit. The pair of fixing members 7a, 7b is made of stainless steel such as SUS316.

In the fixing mechanism 3 according to the embodiment, each of the seals 4 is provided between the outer peripheral surface of the fluidic resistor member 2 and the inner peripheral surface of the fixing member 7a, 7b corresponding thereto. The seal 4 according to the embodiment is an annular seal member made of a resin having excellent durability and chemical resistance, such as a fluororesin, an example of which is PFA.

The seal 4 according to the embodiment also provides sealing between the gasket 6 and the facing surface of the fixing member 7a, 7b corresponding thereto. Specifically, each of the fixing members 7a, 7b has a pressing surface 71 on the facing surface, the pressing surface 71 being inclined and being provided to press the seal 4 against the outer peripheral surface of the fluidic resistor member 2 and against the facing surface of the gasket 6. The pressing surface 71 is provided to the opening of the through-hole in the fixing member 7a, 7b, the opening being provided on the side facing the gasket. With this configuration, as the fixing member 7a, 7b is pressed toward the gasket 6, the pressing surface 71 of the fixing member 7a, 7b is caused to press the seal 4 against the outer peripheral surface of the fluidic resistor member 2, as well as against the facing surface of the gasket 6, so that seal 4 provides sealing between the fixing member 7a, 7b and the outer peripheral surface of the fluidic resistor member 2, and between the fixing member 7a, 7b and the facing surface of the gasket 6. In other words, in the embodiment, the seals 4 are provided on the ends of the respective fixing members 7a, 7b, on the respective sides facing the gasket. Each of the fixing members 7a, 7b also has a flange 72 on the side facing the gasket.

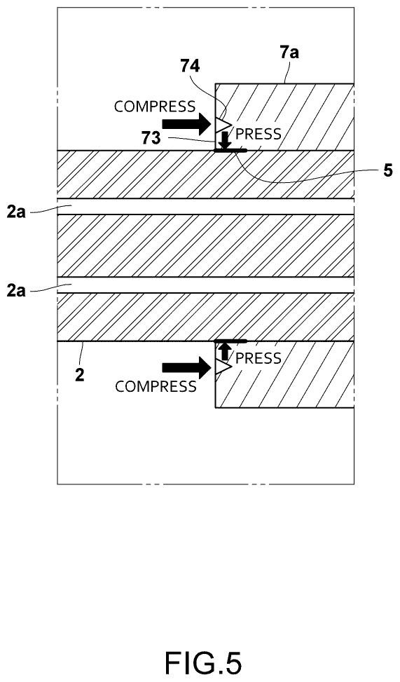

Each of the press-fixing portions 5 is provided to corresponding one of the pair of fixing members 7a, 7b. In the embodiment, the press-fixing portion 5 is provided to an end face of each of the fixing members 7a, 7b, the end face being on the opposite side of the facing surface where the end face is in contact with the gasket 6 (the end on the side facing the gasket). Specifically, the press-fixing portion 5 is formed by deforming an annular portion of the end face of the fixing member 7a, 7b, toward the fluidic resistor member 2, and bringing the annular portion 73 into contact with the fluidic resistor member 2. Each of the fixing members 7a, 7b has an annular groove 74 on the opposite surface, and the portion on the inner side of this groove 74, on the side nearer to the fluidic resistor member 2, serves as the annular portion 73. By then compressing the annular portion 73, as illustrated in FIG. 5, the annular portion 73 comes to press the outer peripheral surface of the fluidic resistor member 2, and forms the press-fixing portion 5.

### Method of Assembling Fixing Mechanism 3

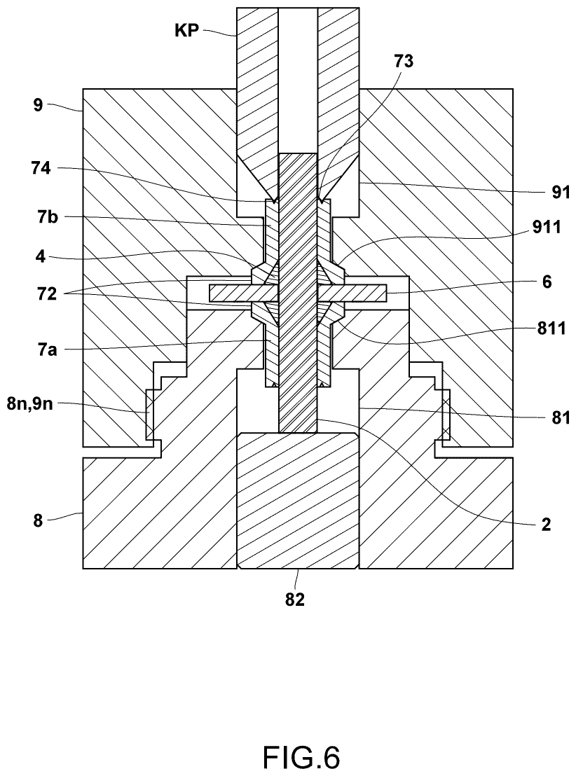

A method of assembling the fixing mechanism 3 will now be explained with reference to FIG. 6.

The gasket 6 is mounted on the fluidic resistor member 2, and the fixing members 7a, 7b are attached to the respective sides of the gasket 6, with the seals 4 nipped between the gasket and the respective fixing members 7a, 7b. In this state, one end of the fluidic resistor member 2 is inserted into a penetrating portion 81 provided in a lower mold 8. Once the one end of the fluidic resistor member 2 is inserted into the penetrating portion 81, a support surface 811 provided in the penetrating portion 81 supports the flange 72 of the fixing member 7a on the one-end side. The penetrating portion 81 is provided with an alignment pin 82 that supports the fluidic resistor member 2 and aligns the fluidic resistor member 2 with respect to the fixing member 7a on the one-end side. The alignment pin 82 can be removed from the lower mold 8.

An upper mold 9 is then fixed to the lower mold 8 in such a manner that the other end of the fluidic resistor member 2 is inserted into a penetrating portion 91 of the upper mold 9. Specifically, the upper mold 9 and the lower mold 8 are fixed to each other by screwing screws 8n, 9n provided to the upper mold 9 and the lower mold 8, respectively. When the other end of the fluidic resistor member 2 is inserted into the penetrating portion 91, and the upper mold 9 is screwed onto the lower mold 8, a pressing surface 92 provided on the penetrating portion 91 of the upper mold 9 presses the flange 72 of the fixing member 7b that is on the side of the other end. As a result, the seals 4 disposed between the gasket 6 and the respective fixing members 7a, 7b are pressure-bonded to the respective fixing members 7a, 7b, the gasket 6, and the fluidic resistor member 2.

A crimping pin KP is then inserted into the penetrating portion 91 of the upper mold 9, and compresses the annular portion 73 against the fluidic resistor member 2, via the groove 74 provided to the fixing member 7b that is on the other-end side. As a result, the other-end side fixing member 7b is fixed to the fluidic resistor member 2.

The alignment pin 82 in the lower mold 8 is then removed, and the upper mold 9 and the lower mold 8 are turned upside down. The crimping pin KP is then inserted into the penetrating portion 81 of the lower mold 8, with the alignment pin 82 removed, and compresses the annular portion 73 against the fluidic resistor member 2 via the groove 74 provided to the fixing member 7a that is on the one-end side. At this time, an alignment pin may be provided to the penetrating portion 91 of the upper mold 9 so that the fluidic resistor member 2 does not become displaced. As a result, the one-end side fixing member 7a is fixed to the fluidic resistor member 2. In the manner described above, the fluidic resistor member 2, the seal 4, and the pair of fixing members 7a, 7b together form an integrated structure (fluidic resistor unit 2U), in a manner aligned with respect to the gasket 6 (see FIG. 4).

### Method of Fixing Fluidic Resistor Member 2 to Channel R

A method of fixing the fluidic resistor member 2 into the channel R will now be explained.

The fluidic resistor unit 2U (see FIG. 4) formed as described above is positioned between the pair of pipe members 11a, 11b prior to being connected. In the embodiment, an alignment holder 18 (see FIG. 2) for aligning the fluidic resistor unit 2U with respect to the other pipe member 11b is used. The alignment holder 18 is a cylindrical holder that is mounted on the outer periphery of the gasket 6, and is mounted on the stepped portion 114 of the other pipe member 11b. With the alignment holder 18 ensuring the alignment between the fluidic resistor unit 2U and the other pipe member 11b, the fluidic resistor unit 2U is disposed between the pair of pipe members 11a, 11b.

By then coupling the pair of pipe members 11a, 11b using the clamp joint that is the coupling mechanism 12, the fluidic resistor unit 2U is fixed by the pair of pipe members 11a, 11b, and the fluidic resistor member 2 is fixed to the channel R. At this time, the protrusions 112 of the respective flanges 111 wedge into the gasket 6, and seal the space between the pair of pipe members 11a, 11b. With the seals 4 providing the seals between the gasket 6 and the fixing members 7a, 7b, respectively, and the seals between the fluidic resistor member 2 and the fixing members 7a, 7b, respectively, the fluid is allowed to flow through the resistor channels 2a of the fluidic resistor member 2.

### Advantageous Effects Achieved by Embodiment

With the fluid measurement apparatus 100 according to the embodiment, because the fluidic resistor member 2 made of a ceramic is used for the fluidic resistor element, highly accurate fluid measurements can be achieved. In particular, in the embodiment, because the seal 4 and the press-fixing portion 5 are provided at positions different from each other in the axial direction of the fluidic resistor member 2, it is not necessary to ensure the sealability by the press-fixing portion 5, and the stress applied to the fluidic resistor member 2 can be reduced. Furthermore, by providing the seal 4 separately from the press-fixing portion 5, it is not necessary to deform the seal 4 using a crimp or the like that is a metal member, and it is possible to use a member having excellent sealability such as a resin member as the seal 4, so that the sealability can be ensured. As a result, it is possible to fix the fluidic resistor member 2 while ensuring the sealability, without applying an unnecessary force to the fluidic resistor member 2.

### Other Embodiments

Note that the present invention is not limited to the embodiment described above.

For example, in the embodiment described above, the seal 4 and the fixing member 7a, 7b are provided on each side of the gasket 6, but the seal 4 and the fixing member 7a may be provided only on the upstream side of the gasket 6.

In the embodiment described above, the annular groove 74 is provided to the opposite surface (end face) of each of the fixing members 7a, 7b, and the press-fixing portion 5 is formed by compressing the portion on the inner side of the annular groove 74. However, the press-fixing portion 5 may be formed by providing a thin cylindrical portion to the end face of each of the fixing members 7a, 7b and by compressing the thin portion.

Furthermore, the seals 4 according to the embodiment described above each provide sealing not only between the outer peripheral surface of the fluidic resistor member 2 and the inner peripheral surface of the fixing member 7a, 7b corresponding thereto, but also between the gasket 6 and the facing surface of the fixing member 7a, 7b corresponding thereto. However, the seals 4 may each be configured to provide sealing only between the outer peripheral surface of the fluidic resistor member 2 and the inner peripheral surface of the fixing member 7a, 7b corresponding thereto. In such a case, seal members each for providing sealing between the gasket 6 and the facing surface of the fixing members 7a, 7b corresponding thereto may be provided separately from the seals 4.

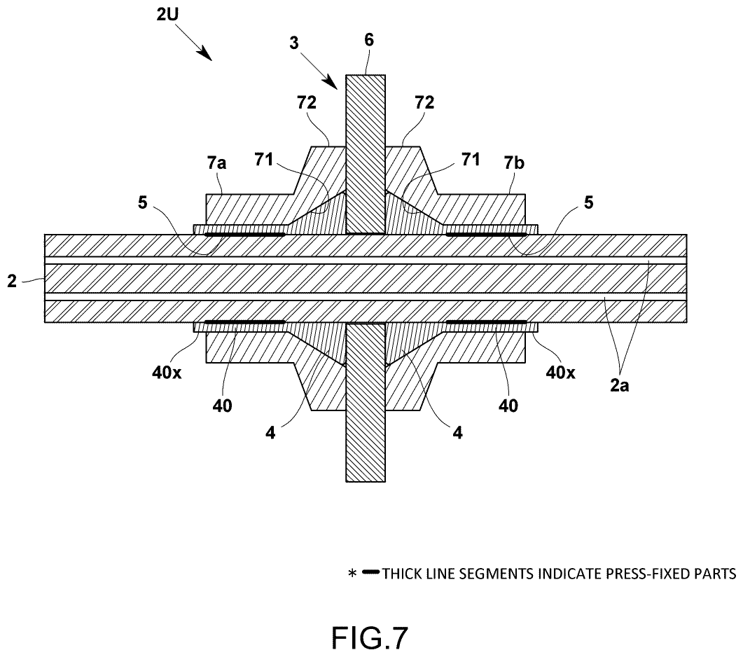

The fixing mechanism 3 may also have a configuration illustrated in FIG. 7. The fixing mechanism 3 illustrated in FIG. 7 includes, in addition to the seals 4 and the press-fixing portions 5, tubular intermediate support portions 40 each provided between the outer peripheral surface of the fluidic resistor member 2 and the inner peripheral surface of the fixing member 7a, 7b corresponding thereto. The intermediate support portion 40 has a circular tubular shape having an equal cross-sectional shape. The inner peripheral surface of the intermediate support portion 40 is in contact with the outer peripheral surface of the fluidic resistor member 2, and the outer peripheral surface of the intermediate support portion 40 is in contact with the inner peripheral surface of the corresponding fixing member 7a, 7b.

The intermediate support portion 40 has an extending portion 40x extending outward from the end face of the corresponding fixing member 7a, 7b, the end face being the end face that is on the opposite side of the end face that is in contact with the gasket 6.

Each of the seals 4 is integrally formed with corresponding one of the intermediate support portions 40. The seal 4 is pressed, by the pressing surface 71 of corresponding one of the fixing members 7a, 7b, against the outer peripheral surface of the fluidic resistor member 2 and against the facing surface of the gasket 6, and provides sealing therebetween. The seal 4 and the intermediate support portion 40 are made of a resin having excellent durability and chemical resistance, such as a fluororesin an example of which is PFA.

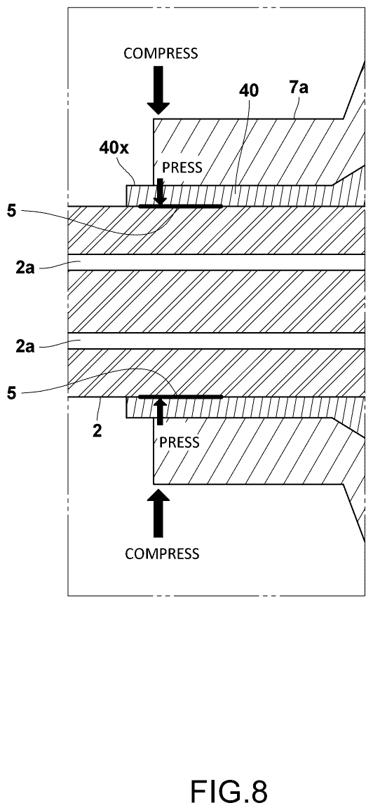

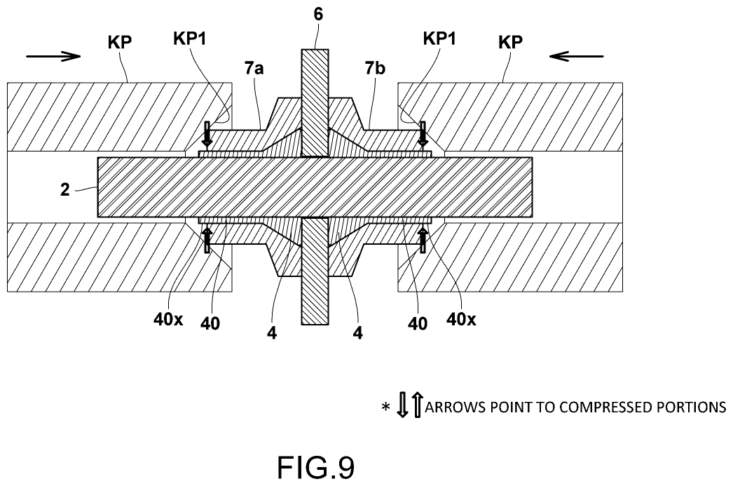

Each of the press-fixing portion 5 is formed of corresponding one of the pair of fixing members 7a, 7b, and is formed as a result of compressing the outer peripheral surface of an end of the fixing member 7a, 7b, the end being on the opposite side of the facing surface where the end face thereof is in contact with the gasket 6 (the end on the side facing gasket). By compressing and deforming the outer peripheral surface of the end of the fixing member 7a, 7b radially inward, as illustrated in FIG. 8, the intermediate support portion 40 is caused to deform, and this intermediate support portion 40 presses the outer peripheral surface of the fluidic resistor member 2, and forms the press-fixing portion 5. Specifically, it is possible to compress the outer peripheral surface of the end of each of the fixing member 7a, 7b by pressing the crimping pin KP against the corner of the end of the fixing member 7a, 7b, as illustrated in FIG. 9. In this manner, the entire end face of the fixing member 7a, 7b is compressed. The crimping pin KP has a tapered pressing surface KP1 that comes into contact with the corner of the outer periphery of the end of the fixing member 7a, 7b.

With such a configuration, the area of the seal can be increased by the intermediate support portion 40, so that the sealing performance can be improved. Furthermore, because the intermediate support portion 40 extends outward, the seal is reliably brought into contact with the end face of the fixing member 7a, 7b, and stable sealing is maintained, so that it is possible to ensure high reliability of the seal over a long time period.

Furthermore, because the press-fixing portion 5 can be formed by compressing the outer peripheral surface of the fixing member 7a, 7b, the compressing processing is not limited to the end face, so that the degree of freedom in processing is improved. In particular, because the pressing force resultant of compression is exerted on the fluidic resistor member 2 in a distributed manner, with the presence of the intermediate support portions 40, concentration of the stress can be alleviated, and a stable seal can be achieved while preventing damage and deformation of the fluidic resistor member 2. In the fixing mechanism 3 illustrated FIG. 7, it is also possible to compress the annular portion 73 formed on the end face of the fixing member 7a, 7b, in the same manner as in the embodiment described above. In such a case, by compressing the annular portion 73, the intermediate support portion 40 is deformed, so that the intermediate support portion 40 forms the press-fixing portion 5 by pressing the outer peripheral surface of the fluidic resistor member 2.

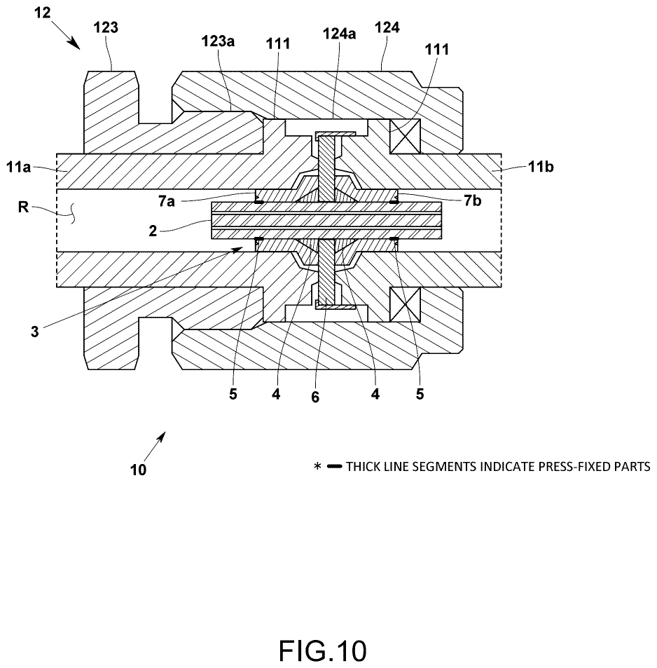

Furthermore, although the coupling mechanism 12 according to the embodiment described above uses a clamp joint, the coupling mechanism 12 may include, as illustrated in FIG. 10, a first nut member 123 fitted onto the outer periphery of one pipe member 11a and having a male thread on the outer peripheral surface, and a second nut member 124 fitted onto the outer periphery of the other pipe member 11b, and having a female thread on the inner periphery and screwed with the male thread. The pair of pipe members 11a, 11b may be connected to each other by screwing the male thread of the first nut member 123 into the female thread of the second nut member 124.

More specifically, the tip end 123a of the first nut member 123 pushes the flange 111 of the one pipe member 11a from the rear side. The second nut member 124 has a housing recess 124a where the flanges 111 of both of the pipe members 11a, 11b provided as the pair are housed, and the bottom surface of this housing recess 124a receives the flange 111 of the other pipe member 11b from the rear side. With such a configuration, by screwing the male thread formed on the first nut member 123 into the female thread formed on the second nut member 124, the first nut member 123 is caused to push the flange 111 of the one pipe member 11a from the rear side, and the second nut member 124 receives the flange 111 of the other pipe member 11b from the rear side, so that the pair of pipe members 11a, 11b is connected to each other.

Moreover, although the embodiment has been applied to the fluid measurement apparatus, the embodiment may be applied to a fluid control apparatus further including a fluid control valve that is provided upstream or downstream of the fluidic resistor member in the channel. Furthermore, the embodiment may include a channel structure in which a ceramic fluidic resistor member is simply provided in the channel, without being applied to the fluid measurement apparatus.

Furthermore, it should be needless to say that the present invention is not limited to the embodiment described above, and various modifications are still possible within the scope not departing from the gist of the present invention.

### REFERENCE CHARACTER LIST

100 fluid measurement apparatus
R channel
10 channel structure
10a, 10b pair of pipe members
2 fluidic resistor member
2a resistor channel
20 upstream pressure sensor
30 downstream pressure sensor
3 fixing mechanism
4 seal
5 press-fixing portion
6 gasket
7a, 7b fixing member
71 pressing surface
73 annular portion
74 groove

What is claimed is:

1. A channel structure comprising:
pipe members each forming a channel through which a fluid flows;
a fluidic resistor member that is made of ceramic, that is provided to the channel, and that has one or more resistor channels; and
a fixing mechanism that fixes the fluidic resistor member to the channel by being nipped between the pipe members, wherein
the fixing mechanism includes:
a seal made of an elastic material that provides sealing on an outer peripheral surface of the fluidic resistor member; and
a press-fixing portion that fixes the fluidic resistor member by pressing the outer peripheral surface of the fluidic resistor member, and
the seal and the press-fixing portion are provided at positions different from each other in an axial direction of the fluidic resistor member.

2. The channel structure according to claim 1, wherein the fixing mechanism further includes:
a gasket that has an annular shape, that is provided on the outer peripheral surface of the fluidic resistor member, and that is nipped between the pipe members; and
a fixing member that has a tubular shape, and is provided on the outer peripheral surface of the fluidic resistor member, on one side or the other side of the gasket, wherein
the seal is provided between the outer peripheral surface of the fluidic resistor member and an inner peripheral surface of the fixing member, to provide sealing between the outer peripheral surface and the inner peripheral surface, and
the press-fixing portion is provided by the fixing member.

3. The channel structure according to claim 2, wherein the fixing member is provided on each of one side and the other side of the gasket, and fixes the gasket by nipping.

4. The channel structure according to claim 2, wherein the seal further provides sealing between the gasket and a facing surface of each of the fixing members.

5. The channel structure according to claim 4, wherein a facing surface of the fixing member has an inclined pressing surface that presses the seal toward the outer peripheral surface of the fluidic resistor member and a facing surface of the gasket.

6. A channel structure comprising:
pipe members each forming a channel through which a fluid flows;
a fluidic resistor member that is made of ceramic, that is provided to the channel, and that has one or more resistor channels;
a fixing mechanism that fixes the fluidic resistor member to the channel by being nipped between the pipe members, wherein
the fixing mechanism includes:
a seal made of an elastic material that provides sealing on an outer peripheral surface of the fluidic resistor member;
a gasket that has an annular shape, that is provided on the outer peripheral surface of the fluidic resistor member, and that is nipped between the pipe members;
a fixing member that has a tubular shape, and that is provided on an outer peripheral surface of the fluidic resistor member on one side or the other side of the gasket;
an intermediate support portion that has a tubular shape, and that is provided between the outer peripheral surface of the fluidic resistor member and an inner peripheral surface of the fixing member; and
a press-fixing portion that fixes the fluidic resistor member by pressing the outer peripheral surface of the fluidic resistor member, wherein
the seal and the press-fixing portion are provided at positions different from each other in an axial direction of the fluidic resistor member, and
the intermediate support portion extends outward from an end face of the fixing member, on an opposite side of an end face that is in contact with the gasket.

7. The channel structure according to claim 6, wherein the press-fixing portion is provided on an opposite side of an end face of the fixing member, the end face being an end face that is in contact with the gasket.

8. The channel structure according to claim 7, wherein
the end face of the fixing member is provided with an annular groove, the end face being the end face on the opposite side of the end face that is in contact with the gasket, and
the press-fixing portion is formed by compressing an inner portion that is nearer to the fluidic resistor member than the groove.

9. The channel structure according to claim 7, wherein the press-fixing portion is formed by compressing an outer peripheral surface of the fixing member, on an opposite side of the end face that is in contact with the gasket.

10. A fluid measurement apparatus comprising:
the channel structure according to claim 1;
an upstream pressure sensor that measures a pressure upstream of the fluidic resistor member in the channel; and
a downstream pressure sensor that measures a pressure downstream of the fluidic resistor member in the channel.

11. A fluid control apparatus comprising:
the channel structure according to claim 1;
an upstream pressure sensor that measures a pressure upstream of the fluidic resistor member in the channel;
a downstream pressure sensor that measures a pressure downstream of the fluidic resistor member in the channel; and
a fluid control valve provided upstream or downstream of the fluidic resistor member in the channel.
